(19) United States
(12) Patent Application Publication
(10) Pub. No.: US 2026/0173680 A1
(43) Pub. Date: Jun. 18, 2026

(54) DISPLAY DEVICE AND METHOD OF MANUFACTURING SAME

(71) Applicant: LG Display Co., Ltd., Seoul (KR)

(72) Inventors: Hyo Young JUN, Paju-si (KR); Jin Seul AHN, Paju-si (KR)

(73) Assignee: LG Display Co., Ltd., Seoul (KR)

(21) Appl. No.: 19/224,118

(22) Filed: May 30, 2025

(30) Foreign Application Priority Data
Dec. 18, 2024 (KR) 10-2024-0189465

(51) Int. Cl. H10K 59/131; H10K 59/12

(52) U.S. Cl. CPC H10K 59/131; H10K 59/1201

(57) ABSTRACT

A display device in some examples includes a display panel having an active area and a non-active area, voltage lines disposed on a substrate in the non-active area, and at least one dummy line disposed adjacent to the voltage lines. The dummy line is positioned at a higher layer than the voltage lines. The display panel includes a polarizing layer and a cover layer adjacent to the polarizing layer.

### CROSS-REFERENCE TO RELATED APPLICATIONS

This application claims priority to Korean Patent Application No. 10-2024-0189465, filed in the Republic of Korea on Dec. 18, 2024, which is hereby expressly incorporated by reference as if fully set forth herein into the present application.

### BACKGROUND OF THE DISCLOSURE

### Field of the Disclosure

The present disclosure relates to a display device and a method of manufacturing the same.

### Discussion of the Related Art

As information technology develops, the market for display devices serving as connecting media between users and information, is growing. Accordingly, the use of display devices such as light emitting display (LED) devices, quantum dot display (QDD) devices, and liquid crystal display (LCD) devices is increasing.

The display devices described above include a display panel including subpixels, a driver that outputs a driving signal to drive the display panel, and a power supply that generates power to be supplied to the display panel or the driver.

The display devices described above can display images by allowing selected subpixels to transmit light or directly emit light when driving signals, such as a scan signal and a data signal, are supplied to the subpixels formed on the display panel.

### SUMMARY OF THE DISCLOSURE

Accordingly, the present disclosure is directed to a display device and a method of manufacturing the same that substantially obviate one or more problems due to limitations and disadvantages of the related art.

An object of the present disclosure is to protect (prevent) voltage lines from corrosion and to delay a moisture penetration path by allowing moisture to preferentially propagate through a dummy shield line even if moisture infiltration occurs through a moisture inflow path.

Another object of the present disclosure is to improve the operational reliability and stability of a device and the service life of the device based on a robust structure that can minimize the possibility of corrosion failure due to moisture infiltration and the like.

Additional advantages, objects, and features of the present disclosure will be set forth in part in the description which follows and in part will become apparent to those having ordinary skill in the art upon examination of the following or can be learned from practice of the present disclosure. The objectives and other advantages of the present disclosure can be realized and attained by the structure particularly pointed out in the written description and claims hereof as well as the appended drawings.

To achieve these objects and other advantages and in accordance with the purpose of the present disclosure, as embodied and broadly described herein, a display device includes a display panel having an active area and a non-active area, voltage lines disposed on a substrate in the non-active area, and at least one dummy line disposed adjacent to the voltage lines, wherein the at least one dummy line is positioned at a higher layer than the voltage lines.

According to aspects of the present disclosure, the display panel can include a polarizing layer and a cover layer adjacent to the polarizing layer, and the at least one dummy line can be disposed between layers adjacent to a surface in contact with the polarizing layer and the cover layer.

According to aspects of the present disclosure, the voltage lines and the at least one dummy line can be formed in multiple layers, and the at least one dummy line can include at least one more layer than the voltage lines.

According to aspects of the present disclosure, the at least one dummy line can be in an electrically floating state.

According to aspects of the present disclosure, the at least one dummy line can be connected to a voltage line.

According to aspects of the present disclosure, the voltage lines can include a gate low voltage line and a second gate low voltage line, and the at least one dummy line can be connected to a dummy voltage line transmitting a voltage lower than one or both of voltages transmitted through the gate low voltage line and the second gate low voltage line.

According to aspects of the present disclosure, the at least one dummy line can include a first shield line layer, a second shield line layer, a third shield line layer, and a fourth shield line layer positioned between the substrate and the polarizing layer.

According to aspects of the present disclosure, the at least one dummy line can include a first shield line layer, a second shield line layer, a third shield line layer, a fourth shield line layer, and a fifth shield line layer positioned between the substrate and the polarizing layer.

In another aspect of the present disclosure, a method of manufacturing a display device includes defining an active area and a non-active area on a substrate, forming voltage lines on the non-active area, and forming at least one dummy line adjacent to the voltage lines, wherein the at least one dummy line is positioned at a higher layer than the voltage lines.

According to aspects of the present disclosure, the method can further include forming a polarizing layer on the active area and the non-active area, and forming a cover layer adjacent to the polarizing layer, wherein at least one dummy line is disposed between layers adjacent to a surface in contact with the polarizing layer and the cover layer.

According to aspects of the present disclosure, the at least one dummy line is disposed on a pixel definition layer that defines an opening of the active area.

It is to be understood that both the foregoing general description and the following detailed description of the present disclosure are examples and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing a display device according to embodiments of the present disclosure;

FIG. 2 is a block diagram showing a configuration of a gate driver in the display device according to embodiments of the present disclosure;

FIG. 3 is a cross-sectional view showing a laminated structure of a display panel according to embodiments of the present disclosure;

FIG. 4 is a plan view showing the front of the display panel according to embodiments of the present disclosure, FIG. 5 is an enlarged view of an area PP1 in FIG. 4 according to a first embodiment of the present disclosure, FIG. 6 is a cross-sectional view showing an area A1-A2 in FIG. 5, and FIG. 7 is a cross-sectional view showing an area B1-B2 in FIG. 5;

FIG. 8 and FIG. 9 are diagrams illustrating a structure in which a dummy shield line is not present according to the first embodiment, and FIG. 10 is a diagram illustrating a structure in which a dummy shield line is present according to the first embodiment; and

FIG. 11 is an enlarged view of the area PP1 in FIG. 4 according to a second embodiment of the present disclosure, and FIG. 12 is a cross-sectional view showing an area C1-C2 in FIG. 11.

### DETAILED DESCRIPTION OF THE EMBODIMENTS

Reference is now made in detail to embodiments of the present disclosure, examples of which can be illustrated in the accompanying drawings. In the following description, where a detailed description of relevant known functions or configurations can unnecessarily obscure aspects of the present disclosure, a detailed description of such known functions or configurations can be omitted for brevity. The progression of processing steps and/or operations described is an example, and the sequence of steps and/or operations is not limited to that set forth herein and can be changed, with the exception of steps and/or operations necessarily occurring in a particular order.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Further, the term “can” encompasses all the meanings and coverages of the term “may” and vice versa. All the components of each display device or apparatus according to all embodiments of the present disclosure are operatively coupled and configured.

A display device according to the present disclosure can be implemented as a light emitting display (LED) device, a quantum dot display (QDD) device, a liquid crystal display (LCD) device, or the like. However, for convenience of description, a light emitting display device that directly emits light based on inorganic light-emitting diodes or organic light-emitting diodes is used as an example of the display device.

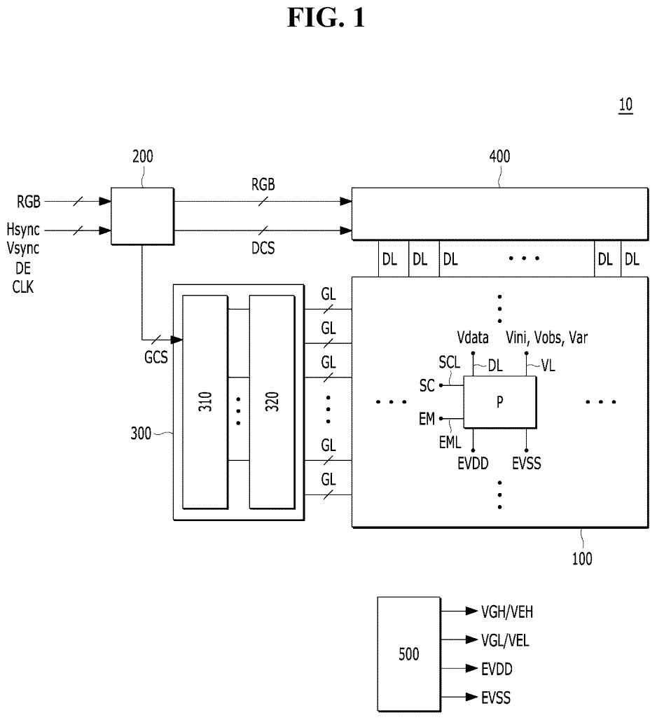

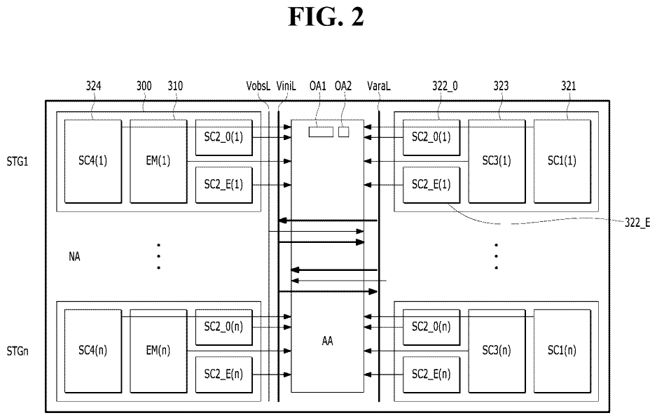

FIG. 1 is a block diagram schematically showing a display device according to embodiments of the present disclosure. FIG. 2 is a block diagram showing a configuration of a gate driver in the display device according to embodiments of the present disclosure.

Referring to FIG. 1, a display device 10 can include a display panel 100 including a plurality of subpixels P, a controller 200, a gate driver (gate driving circuit) 300 that supplies gate signals to the plurality of subpixels P, a data driver (data driving circuit) 400 that supplies data signals (or data voltages) to the plurality of subpixels P, and a power supply 500 that supplies power to the plurality of subpixels P.

The display panel 100 can include an active area (refer to AA in FIG. 2) in which the subpixels P are positioned, and a non-active area (refer to NA in FIG. 2) which is positioned to surround the active area AA and in which the gate driver 300 and the data driver 400 are disposed.

In the display panel 100, a plurality of gate lines GL and a plurality of data lines DL intersect each other, and the plurality of subpixels P can be connected to the gate lines GL and the data lines DL. Specifically, one subpixel P can receive a gate signal from the gate driver 300 through the gate line GL, receive a data voltage (data signal) from the data driver 400 through the data line DL, and receive a high-level voltage EVDD and a low-level voltage EVSS from the power supply 500.

The gate lines GL can transmit a scan signal SC and an emission control signal EM to the plurality of subpixels P, and the data lines DL can transmit a data voltage Vdata to the plurality of subpixels P. According to various embodiments, the gate lines GL can include a plurality of scan lines SCL for supplying the scan signal SC and a plurality of emission control lines EML for supplying the emission control signal EM. The plurality of subpixels P can receive voltages Vini, Var, and Vobs from a plurality of voltage lines VL. The voltages Vini, Var, and Vobs applied through the plurality of voltage lines VL will be described below.

Each of the plurality of subpixels P can include a subpixel driving circuit. The subpixel driving circuit can include a plurality of switching elements, driving elements, capacitors, etc. The switching elements and driving elements, etc. can be configured as thin film transistors. A switching transistor can be switched according to a scan signal SC supplied through a scan line SCL and an emission control signal EM supplied through an emission control line EML. A driving transistor can control the amount of current supplied to a light-emitting element OLED according to a data voltage Vdata (control the amount of emission).

The display panel 100 can be implemented as a non-transmissive display panel or a transmissive display panel. The transmissive display panel can be applied to a transparent display device in which an image is displayed on a screen and an actual object in the background is visible. The display panel 100 can also be implemented as a flexible display panel. The flexible display panel can use a plastic substrate. Each of the plurality of subpixels P can be divided into a red subpixel, a green subpixel, and a blue subpixel for color expression. Each of the plurality of subpixels P can further include a white subpixel.

Touch sensors can be disposed on the display panel 100. Touch input can be sensed using separate touch sensors or through the plurality of subpixels P. The touch sensors can be implemented as on-cell type or add-on type touch sensors disposed on the screen of the display panel or as in-cell type touch sensors built into the display panel 100.

The controller 200 can process image data RGB input from the outside to suit to the size and resolution of the display panel 100 and supply the same to the data driver 400. The controller 200 can generate a gate control signal GCS and a data control signal DCS using external synchronous signals, for example, a dot clock signal CLK, a data enable signal DE, a horizontal synchronization signal Hsync, and a vertical synchronization signal Vsync. The controller 200 can control the operation timing of the gate driver 300 by supplying the gate control signal GCS to the gate driver 300. The controller 200 can control the operation timing of the data driver 400 by supplying the data control signal DCS to the data driver 400. The controller 200 can synchronize the operation timing of the gate driver 300 with the operation timing of the data driver 400 using the gate control signal GCS and the data control signal DCS.

The controller 200 can be configured to be combined with various processors, such as a microprocessor, a mobile processor, and an application processor depending on the device mounted thereon. A host system located in front of the controller 200 can be any one of a television (TV) system, a set-top box, a navigation system, a personal computer (PC), a home theater system, a mobile device, a wearable device, or a vehicle system.

The controller 200 can control the operation timing of a display panel driver at a frame frequency of input frame frequency×i Hz (i being a positive integer greater than 0) by multiplying the input frame frequency by i. The input frame frequency can be 60 Hz in the NTSC (National Television Standards Committee) system and 50 Hz in the PAL (Phase-Alternating Line) system.

The controller 200 can drive the display panel 100 at various refresh rates. The controller 200 can drive the display panel 100 in a variable refresh rate (VRR) mode, for example, in such a manner that the display panel can be switched between a first refresh rate and a second refresh rate.

For example, the controller 200 can drive the display panel 100 at various refresh rates by simply changing the rate of a clock signal, configuring a synchronization signal such that a horizontal blank or a vertical blank is generated, or driving the gate driver 300 in a mask manner. The vertical blank can be defined as a period for matching the timing of input of a data signal and the timing of output (display) of an image on the display panel. The vertical blank can be repeated in one frame cycle, and various signals for the operation of the display device can be synchronized during the period.

The voltage level of the gate control signal GCS output from the controller 200 can be converted into an on voltage and an off voltage through a level shifter and supplied to the gate driver 300. The level shifter can convert a low level voltage of the gate control signal GCS into a gate low voltage VGL and can convert a high level voltage of the gate control signal GCS into a gate high voltage VGH. The gate control signal GCS can include a start pulse signal and a shift clock signal.

The gate driver 300 can supply gate signals to the gate lines GL according to the gate control signal GCS supplied from the controller 200. The gate driver 300 can be disposed on one side or both sides of the display panel 100 in a gate-in-panel (GIP) structure.

The gate driver 300 can sequentially output gate signals to the plurality of gate lines GL under the control of the controller 200. The gate driver 300 can sequentially supply the gate signals to the gate lines GL by shifting the gate signals using a shift register.

The gate signals can include a scan signal SC and an emission control signal EM in an organic light-emitting display device. The scan signal SC can include a scan pulse that swings between the gate low voltage VGL and a gate high voltage VGH. The emission control signal EM can include an emission control signal pulse that swings between a gate on voltage VEL and a gate off voltage VEH. The scan pulse can select subpixels P of a line to which a data voltage Vdata will be written. The emission control signal EM can define an emission time of the subpixels P.

The gate driver 300 can include an emission control signal driver 310 and at least one scan driver 320. The emission control signal driver 310 can output an emission control signal pulse in response to a start pulse and a shift clock from the controller 200 and sequentially shift the emission control signal pulse according to the shift clock. The at least one scan driver 320 can output a scan pulse in response to a start pulse and a shift clock from the controller 200 and shift the scan pulse according to shift clock timing.

The data driver 400 can convert image data RGB into a data voltage Vdata according to a data control signal DCS supplied from the controller 200, and output the data voltage Vdata through a data line DL.

Although FIG. 1 illustrates that one data driver 400 is disposed one side of the display panel 100, the number and positions of data drivers 400 are not limited thereto. For example, the data driver 400 can be composed of a plurality of integrated circuits (ICs) which are disposed on one side of the display panel 100.

The power supply 500 can generate DC power required to drive the subpixel array of the display panel 100 and the display panel driver using a DC-DC converter. The DC-DC converter can include a charge pump, a regulator, a buck converter, a boost converter, etc. The power supply 500 can receive a DC input voltage applied from the host system and generate DC voltages such as gate voltages VGL, VEL, VGH, and VEH, the high-level voltage EVDD, and the low-level voltage EVSS.

Referring to FIG. 1 and FIG. 2, the gate driver 300 can include the emission control signal driver 310 and the scan driver 320. The scan driver 320 can include first to fourth scan drivers 321, 322, 323, and 324. In addition, the second scan driver 322 can include an odd-numbered second scan driver 322_O and an even-numbered second scan driver 322_E.

Shift registers constituting the gate driver 300 can be configured to be symmetrical on both sides of the active area AA. The shift register on one side can include the second scan driver 322_O and 322_E, the fourth scan driver 324, and the emission control signal driver 310, and the shift register on the other side can include the first scan driver 321, the second scan driver 322_O and 322_E, and the third scan driver 323. FIG. 2 illustrates an example in which the odd-numbered second scan driver 322_O and the even-numbered second scan driver 322_E are shared by an odd-numbered subpixel and an even-numbered subpixel. Therefore, the emission control signal driver 310 and the first to fourth scan drivers 321, 322, 323, and 324 can be disposed differently, and the present disclosure is not limited thereto.

Stages STG1 to STGn of the shift register can include first scan signal generators SC1(1) to SC1(n), second scan signal generators SC2_O(1) to SC2_O(n) and SC2_E(1) to SC2_E(n), third scan signal generators SC3(1) to SC3(n), fourth scan signal generators SC4(1) to SC4(n), and emission control signal generators EM(1) to EM(n), respectively. Here, n can be a real number such as an integer greater than 1.

The first scan signal generators SC1(1) to SC1(n) can output first scan signals through first scan lines SC1 of the display panel 100. The second scan signal generators SC2(1) to SC2(n) can output second scan signals through second scan lines SC2 of the display panel 100. The third scan signal generators SC3(1) to SC3(n) can output third scan signals through third scan lines SC3 of the display panel 100. The fourth scan signal generators SC4(1) to SC4(n) can output fourth scan signals through fourth scan lines SC4 of the display panel 100. The emission control signal generators EM(1) to EM(n) can output emission control signals through the emission control lines EM of the display panel 100.

A bias voltage line VobsL for transmitting a bias voltage Vobs, a first initialization voltage line ViniL for transmitting a first initialization voltage Vini, and a second initialization voltage line VaraL for transmitting a second initialization voltage Var can be disposed between the gate driver 300 and the active area AA.

In the drawings, the bias voltage line VobsL, the first initialization voltage line ViniL, and the second initialization voltage line VaraL are illustrated as being located on one of the left side or the right side of the active area AA, but the present disclosure is not limited thereto and they can be located on both sides, and even if located on one side, the location is not limited to the left or right.

Further, one or more optical areas OA1 and OA2 can be disposed in the active area AA. The optical areas OA1 and OA2 can be disposed to overlap one or more optoelectronic devices, such as imaging devices such as a camera (image sensor) and detection sensors such as a proximity sensor and an illuminance sensor.

The optical areas OA1 and OA2 can have a light-transmitting structure formed for the operation of the optoelectronic devices, and thus can have a transmittance of a certain level or higher. In other words, the number of pixels P per unit area in the optical areas OA1 and OA2 can be smaller than the number of pixels P per unit area in the general area other than the optical areas OA1 and OA2 in the active area AA. For example, the resolution of the optical areas OA1 and OA2 can be lower than the resolution of the general area in the active area AA.

The light-transmitting structure in the optical areas OA1 and OA2 can be formed by patterning a cathode in a region where no subpixels are disposed. At this time, the cathode to be patterned can be removed using a laser, or the cathode can be selectively formed and patterned using a material such as a cathode deposition prevention layer.

In addition, the light-transmitting structure in the optical areas OA1 and OA2 can be formed by separately forming the light-emitting element included in the subpixel and the subpixel driving circuit. In other words, the light-emitting element of the subpixel is positioned on the optical areas OA1 and OA2, and a plurality of transistors constituting the subpixel driving circuit is disposed on the periphery of the optical areas OA1 and OA2, and thus the light-emitting element and the subpixel driving circuit can be electrically connected through a transparent metal layer.

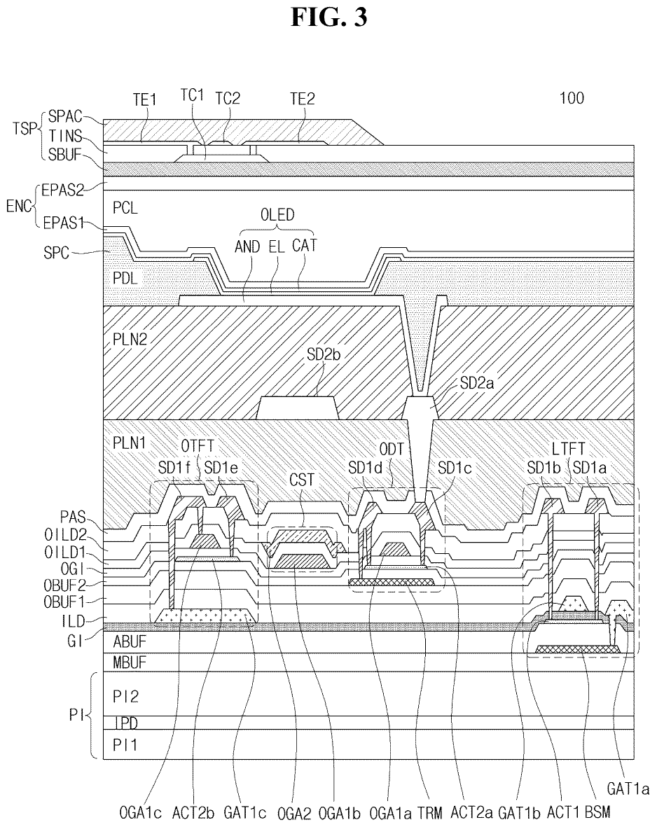

FIG. 3 is a cross-sectional view of a laminated structure of a display panel according to embodiments of the present disclosure.

Referring to FIG. 3, transistors ODT, OTFT, and LTFT and a capacitor CST for driving a light-emitting element OLED can be disposed on a substrate PI of a display panel 100. The transistors ODT, OTFT, and LTFT can include oxide thin film transistors ODT and OTFT including oxide semiconductor materials and a polycrystalline thin film transistor LTFT including polycrystalline semiconductor materials.

The substrate PI can include a first substrate layer PI1, a second substrate layer IPD, and a third substrate layer PI2. The first substrate layer PI1 and the third substrate layer PI2 can be organic films including polyimide, and the second substrate layer IPD located between the first substrate layer PI1 and the third substrate layer PI2 can be an inorganic material (or inorganic film layer) including silicon oxide (SiO₂).

A first buffer layer MBUF can be formed on the substrate PI. The first buffer layer MBUF can be formed by laminating multiple layers of silicon oxide (SiO₂) films to block moisture, etc. that can infiltrate from the outside. A second buffer layer ABUF can be further disposed on the first buffer layer MBUF to protect elements from moisture infiltration. Hereinafter, an example in which the second buffer layer ABUF is provided will be described.

A lower gate insulating layer GI can be positioned on the second buffer layer ABUF, a lower interlayer insulating layer ILD can be positioned on the lower gate insulating layer GI, a first lower buffer layer OBUF1 can be positioned on the lower interlayer insulating layer ILD, and a second lower buffer layer OBUF2 can be positioned on the first lower buffer layer OBUF1.

An upper gate insulating layer OGI can be positioned on the second lower buffer layer OBUF2, a first upper interlayer insulating layer OILD1 can be positioned on the upper gate insulating layer OGI, a second upper interlayer insulating layer OILD2 can be positioned on the first upper interlayer insulating layer OILD1, and an upper passivation layer PPAS can be positioned on the second upper interlayer insulating layer OILD2.

The polycrystalline thin film transistor LTFT can include a first active layer ACT1, a first A gate electrode layer GAT1a, a first B gate electrode layer GAT1b, a first A electrode layer SD1a, and a first B electrode layer SD1b positioned between the second buffer layer ABUF and the upper passivation layer PPAS. The polycrystalline thin film transistor LTFT can further include a first shield layer BSM positioned below the first active layer ACT1. The first A gate electrode layer GAT1a and the first B gate electrode layer GAT1b can be defined as gate metal layers.

The first active layer ACT1 can be positioned on the second buffer layer ABUF, the first A gate electrode layer GAT1a and the first B gate electrode layer GAT1b can be positioned on the lower gate insulating layer GI, and the first A electrode layer SD1a and the first B electrode layer SD1b can be positioned on the second upper interlayer insulating layer OILD2 and can be connected to a first electrode region and a second electrode region of the first active layer ACT1. Although the first B gate electrode layer GAT1b is illustrated as being connected to the first shield layer BSM as an example, the present disclosure is not limited thereto.

The first oxide thin film transistor ODT can include a second active layer ACT2a, a second gate electrode layer OGA1a, a first C electrode layer SD1c, and a first D electrode layer SD1d positioned between the second lower buffer layer OBUF2 and the upper passivation layer PPAS. The first oxide thin film transistor ODT can further include a second shield layer TRM positioned under the second active layer ACT2a. The first oxide thin film transistor ODT can be defined as a driving transistor.

The second active layer ACT2a can be positioned on the second lower buffer layer OBUF2, the second gate electrode layer OGA1a can be positioned on the upper gate insulating layer OGI, and the first C electrode layer SD1c and the first D electrode layer SD1d can be positioned on the second upper interlayer insulating layer OILD2 and can be connected to a first electrode region and a second electrode region of the second active layer ACT2a. Although the first D electrode layer SD1d is illustrated as being connected to the second shield layer TRM as an example, the present disclosure is not limited thereto.

The capacitor CST can include a first electrode layer OGA1b, the first upper insulating layer OILD1, and a second electrode layer OGA2 positioned between the upper gate insulating layer OGI and the second upper interlayer insulating layer OILD2. The first electrode layer OGA1b can be positioned on the upper gate insulating layer OGI, the first upper insulating layer OILD1 can be positioned on the first electrode layer OGA1b, and the second electrode layer OGA2 can be positioned on the first upper insulating layer OILD1. The first electrode layer OGA1b and the second gate electrode layer OGA1a are formed on the same layer and can be made of the same material.

The second oxide thin film transistor OTFT can include a third active layer ACT2b, a third gate electrode layer OGA1c, a first E electrode layer SD1e, and a first F electrode layer SD1f positioned between the second lower buffer layer OBUF2 and the upper passivation layer PPAS. The second oxide thin film transistor OTFT can further include a third shield layer GAT1c positioned below the third active layer ACT2b.

The third active layer ACT2b can be positioned on the second lower buffer layer OBUF2, the third gate electrode layer OGA1c can be positioned on the upper gate insulating layer OGI, and the first E electrode layer SD1e and the first F electrode layer SD1f can be positioned on the second upper interlayer insulating layer OILD2 and can be connected to a first electrode region and a second electrode region of the third active layer ACT2b. Although the first F electrode layer SD1f is illustrated as being connected to the third shield layer GAT1c as an example, the present disclosure is not limited thereto.

A first planarization layer PLN1 can be positioned on the upper passivation layer PPAS, and a second planarization layer PLN2 can be positioned on the first planarization layer PML1. The first planarization layer PLN1 and the second planarization layer PLN2 can be formed of organic materials (or organic film layers). A second A electrode layer SD2a and a second B electrode layer SD2b can be positioned between the first planarization layer PLN1 and the second planarization layer PLN2. The second A electrode layer SD2a can be connected to the first C electrode layer SD1c of the first oxide thin film transistor ODT. The second A electrode layer SD2a can be defined as a connecting electrode layer interconnecting the first C electrode layer SD1c of the first oxide thin film transistor ODT, which corresponds to a driving transistor, and an anode layer AND of the light-emitting element OLED. The first A electrode layer SD1a to the first F electrode layer SD1f can be defined as first source and drain metal layers, and the second A electrode layer SD2a and the second B electrode layer SD2b can be defined as second source and drain metal layers.

The light-emitting element OLED can include the anode layer AND, an emission layer EL, and a cathode layer CAT positioned between the second planarization layer PLN2 and a first passivation layer EPAS1. The anode layer AND can be positioned on the second planarization layer PLN2, the emission layer EL can be positioned on the anode layer AND, and the cathode layer CAT can be positioned on the anode layer AND. The emission layer EL can be positioned on the second planarization layer PLN2 and defined by a pixel definition layer PDL having an opening exposing a part of the anode layer AND. The pixel definition layer PDL can be formed of an organic material (or an organic film layer). The pixel definition layer PDL can include a spacer SPC. The pixel definition layer PDL and the spacer SPC can be formed of the same material or can be formed of different materials.

The cathode layer CAT can be positioned to cover the pixel definition layer PDL along with the emission layer EL. Meanwhile, the light-emitting element OLED can be protected by an encapsulation layer ENC including the first passivation layer EPAS1, an intermediate passivation layer PCL, and a second passivation layer EPAS2, but the present disclosure is not limited thereto.

A touchscreen layer TSP can be positioned on the second passivation layer EPAS2 included in the encapsulation layer ENC. The touchscreen layer TSP can include a touch buffer layer SBUF, a first touch connection electrode layer TC1, a touch insulation layer TINS, touch electrode layers TE1 and TE2, a second touch connection electrode layer TC2, and a touch passivation layer SPAC.

The touch buffer layer SBUF can be positioned on the second passivation layer EPAS2. The first touch connection electrode layer TC1 can be positioned on the touch buffer layer SBUF, the second touch connection electrode layer TC2 can be positioned on the touch insulation layer TINS, and the first touch connection electrode layer TC1 and the second touch connection electrode layer TC2 can electrically connect the first touch electrode layer TE1 and the second touch electrode layer TE2.

The first touch connection electrode layer TC1 and the second touch connection electrode layer TC2 can be disposed to overlap the pixel definition layer PDL to minimize aperture reduction. The first touch electrode layer TE1 and the second touch electrode layer TE2 can be positioned on the touch insulation layer TINS and can be disposed in a first direction and a second direction to intersect each other. The first touch electrode layer TE1 and the second touch electrode layer TE2 can be connected to a touch pad included in a pad area based on a touch routing line.

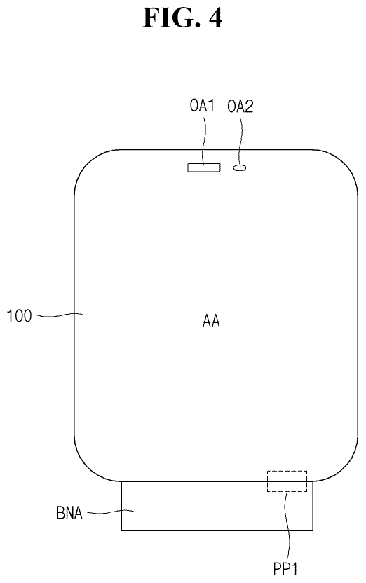

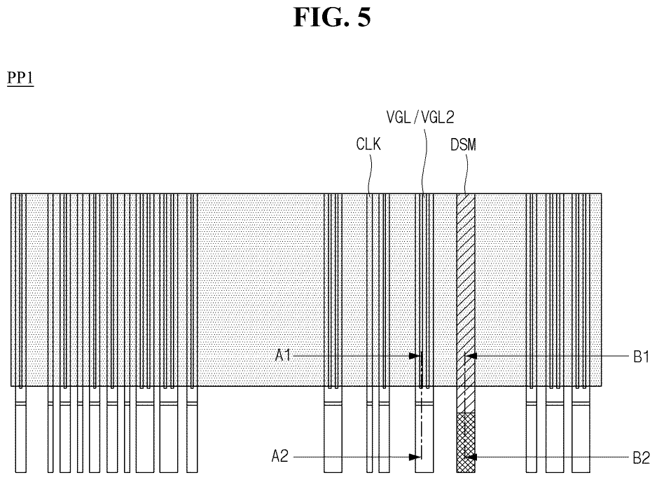

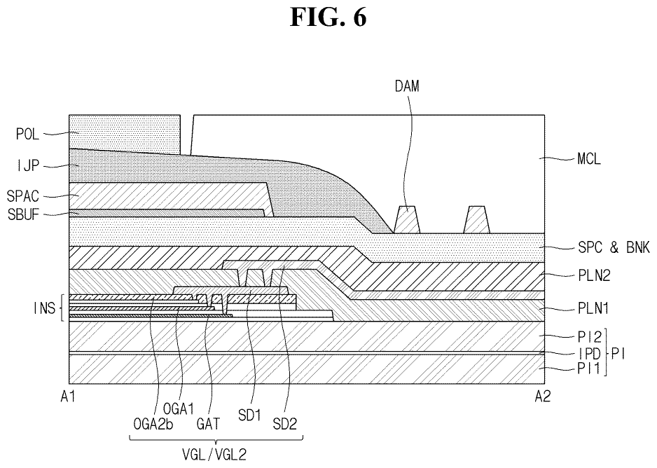

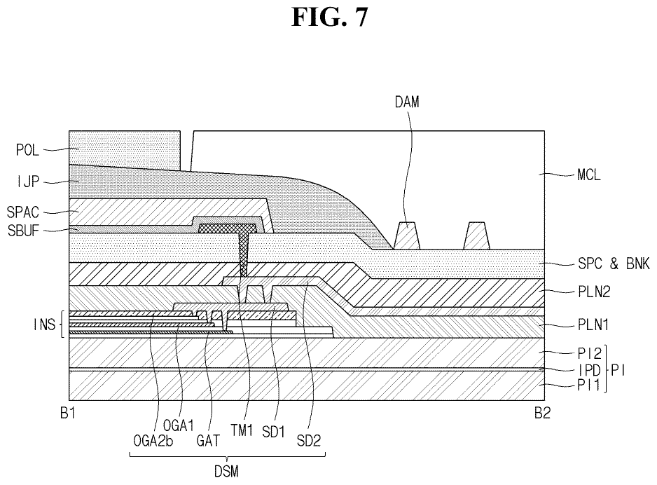

FIG. 4 is a plan view showing the front of the display panel according to embodiments of the present disclosure, FIG. 5 is an enlarged view of an area PP1 in FIG. 4 according to a first embodiment of the present disclosure, FIG. 6 is a cross-sectional view showing an area A1-A2 in FIG. 5, and FIG. 7 is a cross-sectional view showing an area B1-B2 in FIG. 5.

Referring to FIG. 4, the display panel 100 can include an active area AA including optical areas OA1 and OA2, and a banding area BNA including pads for electrical connection with an external circuit board or elements necessary to drive the display panel 100.

Referring to FIG. 4 and FIG. 5, various signal and voltage lines can be located in the lower area of the display panel 100 (which can be described as a non-active area on one side adjacent to the pad area or the banding area) adjacent to the extension BNA.

The various signal and voltage lines can include a clock signal line CLK through which a clock signal is transmitted, a gate low voltage line VGL through which a gate low voltage is transmitted or a second gate low voltage line VGL2 through which a second gate low voltage is transmitted, a dummy shield line DSM, etc. The gate low voltage and the second gate low voltage can have different levels, for example, and the second gate low voltage can have a lower level than the gate low voltage. The dummy shield line DSM can be in an electrically floating state in which a voltage is not transmitted through the dummy shield line DSM.

Referring to FIG. 5 and FIG. 6, the gate low voltage line VGL or the second gate low voltage line VGL2 through which the second gate low voltage is transmitted can be composed of electrode layers positioned between the substrate PI and the second planarization layer PLN2.

More specifically, the gate low voltage line VGL or the second gate low voltage line VGL2 through which the second gate low voltage is transmitted can include first voltage line layers GAT, OGA1, and OGA2b, a second voltage line layer SD1, and a third voltage line layer SD2. The first voltage line layers GAT, OGA1, and OGA2b, the second voltage line layer SD1, and the third voltage line layer SD2 are positioned on different layers, but can be electrically connected through a contact hole formed between the layers.

The first voltage line layers GAT, OGA1, and OGA2b can include at least one of a first lower electrode layer GAT, a second lower electrode layer OGA1, and a third lower electrode layer OGA2b interposed between insulating layers INS positioned on the substrate PI. The first lower electrode layer GAT, the second lower electrode layer OGA1, and the third lower electrode layer OGA2b interposed between the insulating layers INS can be electrode layers positioned between the lower gate insulating layer GI and the second upper interlayer insulating layer OILD2 in FIG. 3.

The second voltage line layer SD1 can be positioned on a second upper interlayer insulating layer OILD2 included in the insulating layers INS. The second voltage line layer SD1 can be an electrode layer positioned on the second upper interlayer insulating layer OILD2 in FIG. 3. The second voltage line layer SD1 can be defined as a first source and drain electrode layer.

The third voltage line layer SD2 can be positioned on a first planarization layer PLN1 positioned on the second voltage line layer SD1. The third voltage line layer SD2 can be an electrode layer positioned on the first planarization layer PLN1 in FIG. 3. In other words, the third voltage line layer SD2 can be defined as a second source and drain electrode layer.

A second planarization layer PLN2 can be positioned on the third voltage line layer SD2, a spacer and pixel definition layer SPC & BNK can be positioned on the second planarization layer PLN2, a touch buffer layer SBUF and a dam DAM can be positioned on the spacer and pixel definition layer SPC & BNK, a touch passivation layer SPAC can be positioned on the touch buffer layer SBUF, a dummy passivation layer IJP can be positioned on the touch passivation layer SPAC, and a polarizing layer POL and a cover layer MCL can be positioned on the dummy passivation layer IJP. The polarizing layer POL has polarization characteristics. The cover layer MCL can be formed to have a flat structure to have a surface height similar or identical to that of the polarizing layer POL.

Referring to FIG. 5 and FIG. 7, the dummy shield line DSM can be composed of electrode layers positioned between the substrate PI and the touch buffer layer SBUF.

More specifically, the dummy shield line DSM can include first shield line layers GAT, OGA1, and OGA2b, a second shield line layer SD1, a third shield line layer SD2, and a fourth shield line layer TM1. The dummy shield line DSM can include only the fourth shield line layer TM1.

The first shield line layers GAT, OGA1, and OGA2b, the second shield line layer SD1, and the third shield line layer SD2 can be formed of the same materials and on the same layer as the first voltage line layers GAT, OGA1, and OGA2b, the second voltage line layer SD1, and the third voltage line layer SD2 described in FIG. 6. Therefore, refer to FIG. 6 for description thereof.

The fourth shield line layer TM1 can be located on the spacer and pixel definition layers SPC & BNK. The first voltage line layers GAT, OGA1, and OGA2b, the second voltage line layer SD1, the third voltage line layer SD2, and the fourth shield line layer TM1 are located on different layers, but can be electrically connected through contact holes formed between the layers.

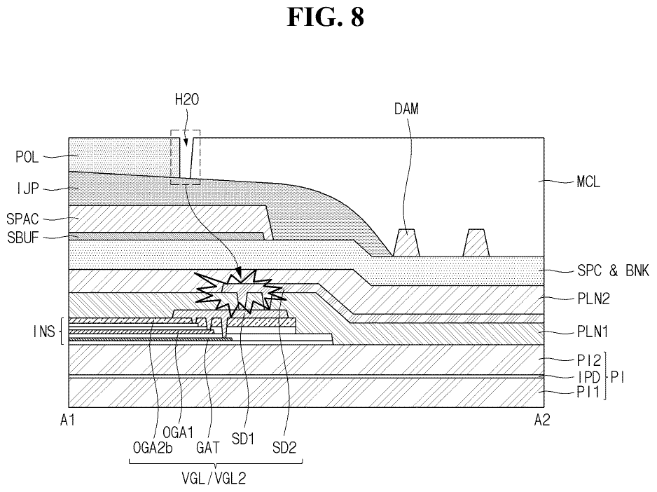

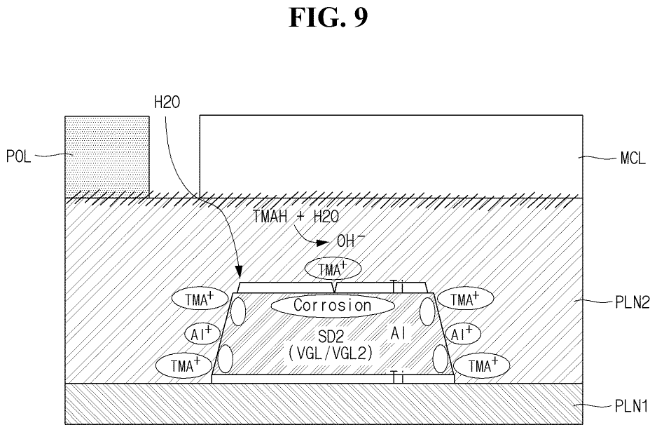

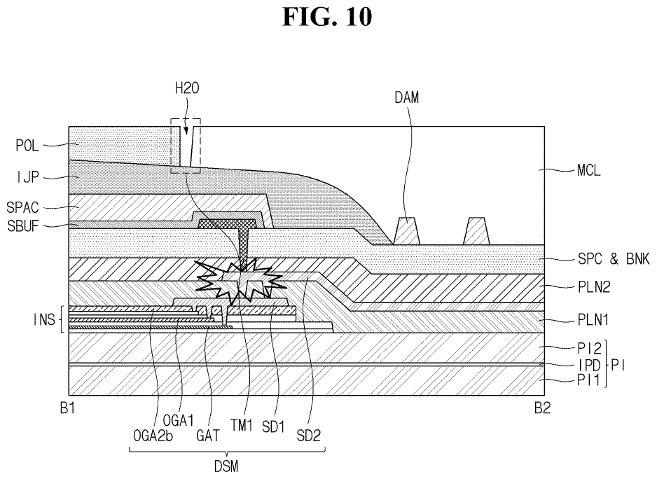

FIG. 8 and FIG. 9 are diagrams illustrating a structure in which a dummy shield line is not present according to the first embodiment, and FIG. 10 is a diagram illustrating a structure in which a dummy shield line is present according to the first embodiment.

Referring to FIG. 8, a gap can be present between the polarizing layer POL and the cover layer MCL. The gap can be formed during a process, formed as the usage period increases, formed under a high-temperature reliability environment, or formed for various reasons. The gap can be formed due to shrinkage and expansion of the polarizing layer POL.

If a gap is present between the polarizing layer POL and the cover layer MCL as described above, moisture (indicated as ‘H₂O’) can infiltrate from the outside and flow into the inside of the display panel, which can generate a moisture inflow path. The moisture inflow path can be formed through an organic film layer in which moisture (H₂O) propagates relatively well.

Moisture (H₂O) that has infiltrated through the moisture inflow path can be transmitted to the gate low voltage line VGL or the second gate low voltage line VGL2 that occupies the highest layer in the area related to the moisture inflow path.

Referring to FIG. 9, moisture (H₂O) that has infiltrated through the moisture inflow path can affect the third voltage line layer SD2 that constitutes the uppermost layer in the gate low voltage line VGL or the second gate low voltage line VGL2. Hereinafter, an example in which the third voltage line layer SD2 is formed of a titanium/aluminum/titanium (Ti/Al/Ti) alloy will be described.

Moisture (H₂O) that has infiltrated through the moisture inflow path can react with tetramethylammonium hydroxide (TMAH), which is one of etching components remaining between layers, and generate ions (OH—, TMA+). Such ions (OH—, TMA+) can chemically react with the titanium/aluminum/titanium (Ti/Al/Ti) alloy forming the third voltage line layer SD2, causing corrosion of aluminum Al.

Referring to FIG. 10, when the dummy shield line DSM according to the first embodiment is provided, moisture (H₂O) that has infiltrated through a gap between the polarizing layer POL and the cover layer MCL can be transmitted to the dummy shield line DSM that occupies the highest layer in the area. For example, when the dummy shield line DSM according to the first embodiment is provided, moisture (H₂O) that has infiltrated through the moisture inflow path can be transmitted through the dummy shield line DSM that is disposed above the gate low voltage line VGL or the second gate low voltage line VGL2. In other words, the first embodiment can induce moisture transmission to occur to the dummy shield line DSM that is not used to drive the display panel.

Therefore, according to the first embodiment, when moisture (H₂O) infiltration occurs through the moisture inflow path, the moisture is preferentially transmitted through the dummy shield line DSM, and thus voltage lines including the gate low voltage line VGL or the second gate low voltage line VGL2 can be protected (prevented) from corrosion and a moisture infiltration path can be delayed.

As such, according to the first embodiment of the present disclosure, it is possible to improve the operational reliability and stability and service life of the display device based on a robust structure that can minimize the possibility of corrosion failure due to moisture infiltration, etc. In addition, it is possible to improve the display quality by preventing or minimizing corrosion of voltage lines and reducing the occurrence rate of image abnormality (or image defects).

In order to achieve the above effects, the dummy shield line DSM is preferably disposed between layers adjacent to the surface in contact with the polarizing layer POL and the cover layer MCL, but the present disclosure is not limited thereto. Additionally, in the first embodiment, only one dummy shield line DSM is shown, but multiple dummy shield lines can be provided.

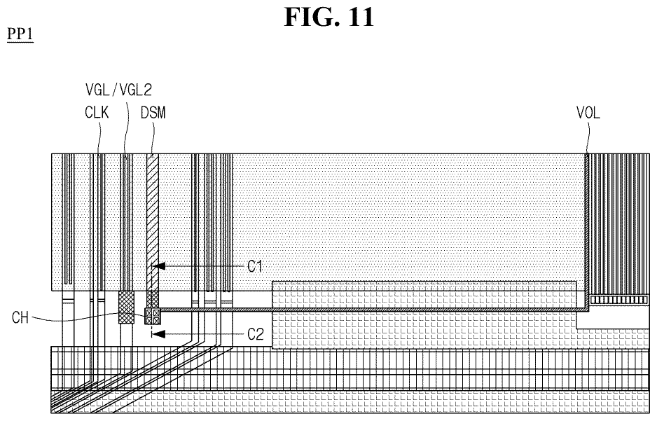

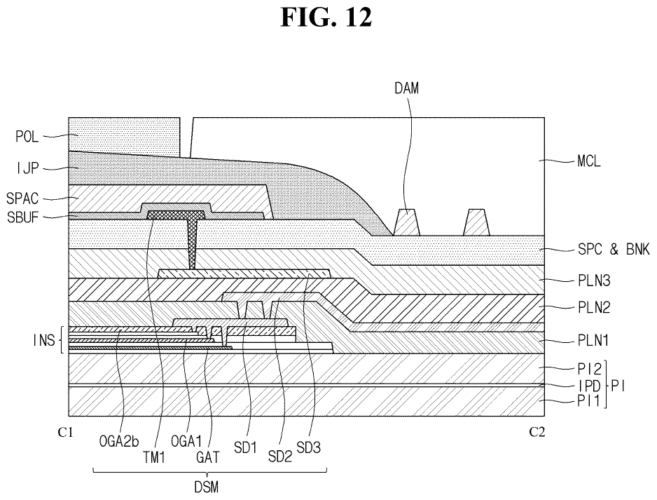

FIG. 11 is an enlarged view of the area PP1 in FIG. 4 according to a second embodiment of the present disclosure, and FIG. 12 is a cross-sectional view showing an area C1-C2 in FIG. 11.

Referring to FIG. 11, various signal lines can be positioned in the lower area of the display panel 100. For example, a clock signal line CLK through which a clock signal is transmitted, a gate low voltage line VGL through which a gate low voltage is transmitted or a second gate low voltage line VGL2 through which a second gate low voltage is transmitted, a dummy shield line DSM, and a dummy voltage line VOL can be positioned.

Referring to FIG. 11 and FIG. 12, the dummy shield line DSM can include first shield line layers GAT, OGA1, and OGA2b, a second shield line layer SD1, a third shield line layer SD2, a fourth shield line layer SD3, and a fifth shield line layer TM1. The dummy shield line DSM can include only the fourth shield line layer SD3 and the fifth shield line layer TM1.

The first shield line layers GAT, OGA1, and OGA2b, the second shield line layer SD1, the third shield line layer SD2, the fourth shield line layer SD3, and the fifth shield line layer TM1 are positioned on different layers, but can be electrically connected through contact holes formed between the layers.

The first shield line layers GAT, OGA1, and OGA2b can include at least one of a first lower electrode layer GAT, a second lower electrode layer OGA1, and a third lower electrode layer OGA2b interposed between insulating layers INS positioned on the substrate PI. The first lower electrode layer GAT, the second lower electrode layer OGA1, and the third lower electrode layer OGA2b interposed between the insulating layers INS can be electrode layers positioned between the lower gate insulating layer GI and the second upper interlayer insulating layer OILD2 in FIG. 3.

The second shield line layer SD1 can be positioned on the second upper interlayer insulating layer OILD2 included in the insulating layers INS. The second shield line layer SD1 can be an electrode layer positioned on the second upper interlayer insulating layer OILD2 in FIG. 3. The second shield line layer SD1 can be defined as a first source and drain electrode layer.

The third shield line layer SD2 can be positioned on the first planarization layer PLN1 positioned on the second shield line layer SD1. The third shield line layer SD2 can be an electrode layer positioned on the first planarization layer PLN1 in FIG. 3. In other words, the third shield line layer SD2 can be defined as a second source and drain electrode layer.

The fourth shield line layer SD3 can be positioned on the second planarization layer PLN2 positioned on the third shield line layer SD2. The fourth shield line layer SD3 can be an electrode layer newly added onto the second planarization layer PLN2 in FIG. 3. In other words, the fourth shield line layer SD3 can be defined as a third source and drain electrode layer.

The fifth shield line layer TM1 can be positioned on a third planarization layer PLN3 positioned on the fourth shield line layer SD3. The fifth shield line layer TM1 can be an insulating layer newly added between the second planarization layer PLN2 and the spacer and pixel definition layer SPC & BNK in FIG. 3.

The second planarization layer PLN2 and the third planarization layer PLN3 can be positioned between the fourth shield line layer SD3 and the fifth shield line layer TM1, the spacer and pixel definition layer SPC & BNK can be positioned on the third planarization layer PLN3, a touch buffer layer SBUF and a dam DAM covering the fifth shield line layer TM1 can be positioned on the spacer and pixel definition layer SPC & BNK, a touch passivation layer SPAC can be positioned on the touch buffer layer SBUF, a dummy passivation layer IJP can be positioned on the touch passivation layer SPAC, and a polarizing layer POL and a cover layer MCL can be positioned on the dummy passivation layer IJP.

The fifth shield line layer TM1 can be electrically connected to a dummy voltage line VOL that is spaced apart from the fifth shield line layer TM1. The fifth shield line layer TM1 and the dummy voltage line VOL can be electrically connected through a contact hole CH. The fifth shield line layer TM1 and the dummy voltage line VOL can have the same laminated structure or different laminated structures. The dummy voltage line VOL can transmit a lower voltage than one or both of voltages transmitted through the gate low voltage line VGL and the second gate low voltage line VGL2.

In the second embodiment, when moisture (H₂O) infiltrates through a moisture inflow path, moisture is preferentially transmitted through the dummy shield line DSM, and thus voltage lines including the gate low voltage line VGL or the second gate low voltage line VGL2 can be protected (prevented) from corrosion, and the moisture infiltration path can be delayed.

Accordingly, the display device according to the second embodiment of the present disclosure can improve operational reliability, operational stability, and service life based on a robust structure that can minimize the possibility of corrosion failure due to moisture infiltration, etc.

As described above, the present disclosure has the effect of protecting (preventing) voltage lines from corrosion and delaying a moisture penetration path by allowing moisture to preferentially propagate through a dummy shield line even if moisture infiltration occurs through a moisture inflow path. In addition, the present disclosure has the effect of improving display quality by preventing or minimizing corrosion of voltage lines and reducing the occurrence rate of image abnormalities (or image defects). Furthermore, the present disclosure has the effect of improving the operational reliability and stability of a device and the service life of the device based on a robust structure that can minimize the possibility of corrosion failure due to moisture infiltration, etc.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device comprising:
a display panel having an active area and a non-active area;
voltage lines disposed on a substrate in the non-active area; and
at least one dummy line disposed adjacent to the voltage lines,
wherein the at least one dummy line is positioned at a higher layer than the voltage lines.

2. The display device of claim 1, wherein the display panel comprises a polarizing layer and a cover layer adjacent to the polarizing layer,
wherein the at least one dummy line is disposed between layers adjacent to a surface in contact with the polarizing layer and the cover layer.

3. The display device of claim 1, wherein the voltage lines and the at least one dummy line are formed in multiple layers, and the at least one dummy line includes at least one more layer than the voltage lines.

4. The display device of claim 1, wherein the at least one dummy line is in an electrically floating state.

5. The display device of claim 1, wherein the at least one dummy line is connected to a voltage line.

6. The display device of claim 1, wherein the voltage lines comprise a gate low voltage line and a second gate low voltage line, and
wherein the at least one dummy line is connected to a dummy voltage line configured to transmit a voltage lower than one or both of voltages configured to be transmitted through the gate low voltage line and the second gate low voltage line.

7. The display device of claim 1, wherein the at least one dummy line comprises a first shield line layer, a second shield line layer, a third shield line layer, and a fourth shield line layer positioned between the substrate and a polarizing layer.

8. The display device of claim 1, wherein the at least one dummy line comprises a first shield line layer, a second shield line layer, a third shield line layer, a fourth shield line layer, and a fifth shield line layer positioned between the substrate and a polarizing layer.

9. A method of manufacturing a display device, the method comprising:
defining an active area and a non-active area on a substrate;
forming voltage lines in the non-active area; and
forming at least one dummy line adjacent to the voltage lines,
wherein the at least one dummy line is positioned at a higher layer than the voltage lines.

10. The method of claim 9, further comprising:
forming a polarizing layer in the active area and the non-active area; and
forming a cover layer adjacent to the polarizing layer,
wherein the at least one dummy line is disposed between layers adjacent to a surface in contact with the polarizing layer and the cover layer.

11. The method of claim 9, wherein the voltage lines and the at least one dummy line are formed in multiple layers, and the at least one dummy line includes at least one more layer than the voltage lines.

12. The method of claim 9, wherein the at least one dummy line is in an electrically floating state.

13. The method of claim 9, wherein the at least one dummy line is connected to a voltage line.

14. The method of claim 9, wherein the voltage lines comprise a gate low voltage line and a second gate low voltage line, and
wherein the at least one dummy line is connected to a dummy voltage line configured to transmit a voltage lower than one or both of voltages configured to be transmitted through the gate low voltage line and the second gate low voltage line.

15. The method of claim 9, wherein the at least one dummy line is disposed on a pixel definition layer that defines an opening of the active area.
